(19) United States
(12) Patent Application Publication
(10) Pub. No.: US 2024/0122037 A1
(43) Pub. Date: Apr. 11, 2024

(54) DISPLAY DEVICE

(71) Applicant: SAMSUNG DISPLAY CO., LTD., YONGIN-SI (KR)

(72) Inventors: Jae Heung HA, YONGIN-SI (KR); Jong Woo KIM, YONGIN-SI (KR); So Young OH, YONGIN-SI (KR); Woo Suk JUNG, YONGIN-SI (KR); Hee Yeon PARK, YONGIN-SI (KR); Chang Yeong SONG, YONGIN-SI (KR); Jong Kwang YUN, YONGIN-SI (KR)

(21) Appl. No.: 18/339,148

(22) Filed: Jun. 21, 2023

(30) Foreign Application Priority Data
Oct. 6, 2022 (KR) 10-2022-0128188
Feb. 8, 2023 (KR) 10-2023-0016804

(51) Int. Cl. H10K 59/80; H10K 71/00

(52) U.S. Cl. CPC H10K 59/8722; H10K 71/851; H10K 2102/351

(57) ABSTRACT

A display device includes a substrate that includes a display area and a non-display area, a display element layer disposed on the display area of the substrate, an opposing substrate that faces the substrate and the display element layer, a sealing member disposed on the non-display area and that couples the substrate and the opposing substrate, and a filler disposed between the substrate and the opposing substrate. A thickness of the filler varies in the range of 60% to 400% of a thickness of the sealing member.

### CROSS-REFERENCE TO RELATED APPLICATION

This application claims priority under 35 U.S.C. 119 from Korean Patent Application No. 10-2022-0128188, filed on Oct. 6, 2022, and Korean Patent Application No. 10-2023-0016804, filed on Feb. 8, 2023, both in the Korean Intellectual Property Office, the contents of both of which are herein incorporated by reference in their entireties.

### TECHNICAL FIELD

Embodiments of the present disclosure are directed to a display device.

### DISCUSSION OF THE RELATED ART

As an information society develops, the demand has increased for display devices that display an image in various forms. For example, display devices have been incorporated into various electronic devices, such as smartphones, digital cameras, laptop computers, navigation devices, and smart televisions.

A display device is a flat panel display device such as a liquid crystal display device, a field emission display device, or a light emitting display device. A light emitting display device may be an organic light emitting display device that includes an organic light emitting element, an inorganic light emitting display device that includes an inorganic light emitting element such as an inorganic semiconductor, or a subminiature light emitting display device that includes a subminiature light emitting element.

An organic light emitting element includes two opposing electrodes and a light emitting layer interposed therebetween. The light emitting layer receives electrons and holes from the two electrodes and recombines the electronic and the holes to generate excitons, and the generated excitons decay from an excited state to a ground state, thereby emitting light.

An organic light emitting display device that includes an organic light emitting element can be configured in a light weight and thin shape with low power consumption because it does not require a light source such as a backlight unit, and also has a wide viewing angle, high luminance and contrast, and a fast response speed.

### SUMMARY

Embodiments of the present disclosure provide a display device with fewer display defects and increased reliability.

According to an embodiment of the present disclosure, a display device includes a substrate that includes a display area and a non-display area, a display element layer disposed on the display area of the substrate, an opposing substrate that faces the substrate and the display element layer, a sealing member disposed on the non-display area and that couples the substrate and the opposing substrate, and a filler disposed between the substrate and the opposing substrate. A thickness of the filler ranges from 60% to 400% of a thickness of the sealing member.

In an embodiment, the thickness of the filler increases from the non-display area toward the display area.

In an embodiment, the thickness of the filler increases from the non-display area toward a center of the display area.

In an embodiment, the thickness of the filler decreases and then increases from the sealing member toward a center of the display area.

In an embodiment, the substrate and the opposing substrate each include glass.

In an embodiment, the filler is in direct contact with the substrate, the display element layer, and the opposing substrate.

In an embodiment, the filler includes at least one of an acrylate resin that contains silicon, an epoxy resin that contains silicon, a viny-based resin that contains silicon, or a phenyl-based resin that contains silicon.

In an embodiment, the filler further includes silylidyne.

In an embodiment, the filler is spaced apart from the sealing member and covers the display element layer.

In an embodiment, the filler is in contact with the sealing member and fills a space between the substrate and the opposing substrate.

In an embodiment, the filler has a viscosity of 1,000 to 100,000 cP.

According to an embodiment of the present disclosure, a display device includes a substrate, a display element layer disposed on the substrate, an opposing substrate that faces the substrate and includes a first area that overlaps the display element layer, a second area that surrounds the first area, and a third area that surrounds the second area, a sealing member that couples the substrate and the opposing substrate, and a filler that covers the display element layer and is in contact with the substrate and the opposing substrate. The filler has different thicknesses in the first area, the second area, and the third area.

In an embodiment, heights of the first area, the second area, and the third area of the opposing substrate measured from an upper surface of the substrate differ from each other.

In an embodiment, the height of the first area is higher than the height of each of the second area and the third area.

In an embodiment, the height of the second area increases from the third area toward the first area.

In an embodiment, the height of the second area decreases and then increases from the third area toward the first area.

In an embodiment, the first area and the third area are flat.

In an embodiment, the third area overlaps the sealing member.

In an embodiment, the thickness of the filler ranges from 60% to 400% of a thickness of the sealing member.

In an embodiment, the filler has a viscosity of 1,000 to 100,000 cP.

According to an embodiment of the present disclosure, a method of manufacturing a display device includes disposing a display element layer on an upper surface of a mother substrate and forming a plurality of first cell areas, forming an outer sealant and a sealing member on an upper surface of a mother encapsulation substrate, where the mother encapsulation substrate includes a plurality of second cell areas that overlap the plurality of first cell areas, applying a filling material to the mother encapsulation substrate, bonding the mother encapsulation substrate to the mother substrate, where the mother encapsulation substrate acquires a shape that is convex in a third direction perpendicular to the upper surface of the mother substrate by the applied filling material, curing the sealing member and the filling material so that a filler is formed, and obtaining a display device by cutting the bonded mother substrate and mother encapsulation substrate.

In an embodiment, a plurality of display elements are disposed in a grid pattern on the mother substrate, and the display element layer is disposed in each of the plurality of first cell areas.

In an embodiment, the second cell areas are arranged in a grid pattern on the mother encapsulation substrate, and the outer sealant couples edges of the mother encapsulation substrate and the mother substrate and encloses the second cell areas.

In an embodiment, the filling material is applied as a plurality of dots in a grid pattern through a jet dispenser, and are spaced apart from the sealing member.

In an embodiment, the filling material includes a material that has little reactivity with the display element layer and has a refractive index of 1.4 or more and 1.5 or less.

In an embodiment, bonding the mother substrate and the mother encapsulation substrate includes a thermo-compression process that applies a laser to the sealing member, wherein the filling material spreads toward the sealing member in a space surrounded by the mother encapsulation substrate, the mother substrate, and the sealing member, and the mother encapsulation substrate becomes convex in the third direction in an area that faces the display element layer.

In an embodiment, the sealing member is irradiated with a laser beam that partially melts the sealing member so that the mother substrate and the mother encapsulation substrate are bonded to each other.

In an embodiment, curing the sealing member and the filling material includes at least one of thermal curing, UV curing, or thermal curing and UV curing at the same time.

According to the display device according to an embodiment, by forming a thickness of a filler in the range of 60 to 400% as compared to a thickness of a sealing member, display defects and reliability degradation can be prevented.

Further, by forming the filler between a substrate and an opposing substrate, permeation of moisture and oxygen into a display element layer can be prevented and durability of the display device can be further increased.

### BRIEF DESCRIPTION OF THE DRAWINGS

FIG. 1 is a schematic plan view of a display device according to an embodiment.

FIG. 2 is a schematic cross-sectional view of a display device according to an embodiment.

FIG. 3 illustrates lines in a display device according to an embodiment.

FIG. 4 is an equivalent circuit diagram of a sub-pixel according to an embodiment.

FIG. 5 is a schematic cross-sectional view one of a sub-pixel of a display device according to an embodiment.

FIG. 6 is a plan view of a display device according to an embodiment.

FIG. 7 is a cross-sectional view taken along line Q1-Q1′ of FIG. 6.

FIG. 8 is a plan view of a portion of a display device according to an embodiment.

FIG. 9 is a cross-sectional view of a portion of a display device according to an embodiment.

FIG. 10 is a cross-sectional view of a display device according to an embodiment.

FIG. 11 is a plan view of a portion of a display device according to an embodiment.

FIG. 12 is a cross-sectional view of a display device according to an embodiment.

FIG. 13 is a cross-sectional view of a display device according to an embodiment.

FIG. 14 is a flowchart of a method for manufacturing a display device according to an embodiment.

FIGS. 15 to 28 illustrate a method for manufacturing a display device according to an embodiment.

### DETAILED DESCRIPTION

It will be understood that when a layer is referred to as being “on” another layer or substrate, it can be directly on the other layer or substrate, or intervening layers may also be present. The same reference numbers may indicate the same components throughout the specification.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described with reference to the accompanying drawings.

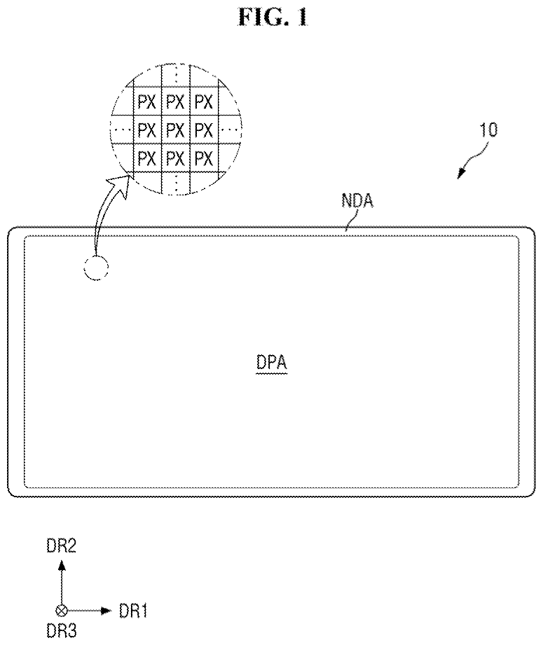

FIG. 1 is a schematic plan view of a display device according to an embodiment.

In the present specification, the terms “upper portion”, “top”, and “upper surface” refer to an upper direction based on a display device 10, that is, one direction in a third direction DR3, and the terms “lower portion”, “bottom”, and “lower surface” refer to the other direction in the third direction DR3. In addition, the terms “left”, “right”, “upper”, and “lower” refer to directions when the display device 10 is viewed in a plan view. For example, the term “right” refers to one direction in a first direction DR1, the term “left” refers to the other direction in the first direction DR1, the term “upper” refers to one direction in a second direction DR2, and the term “lower” refers to the direction in the second direction DR2. In an embodiment, the first direction DR1, the second direction DR2, and the third direction DR3 are mutually orthogonal.

Referring to FIG. 1, in an embodiment, a display device 10 may display a moving image or a still image. The display device 10 may be any electronic device that provides a display screen. For example, the display device 10 may any device that provides a display screen, such as a television, a laptop computer, a monitor, a billboard, an Internet of thing device, a mobile phone, a smartphone, a tablet personal computer (PC), an electronic watch, a smartwatch, q watch phone, a head mounted display, a mobile communication terminal, an electronic notebook, an electronic book, a portable multimedia player (PMPs), a navigation device, a game console, a digital camera, a camcorder, etc.

The display device 10 includes a display panel that provides a display screen. Examples of a display panel include an inorganic light emitting diode display panel, an organic light emitting display panel, a quantum dot light emitting display panel, a plasma display panel, and a field emission display panel. Hereinafter, an inorganic light emitting diode display panel is described as an example of a display panel, but embodiments of the present disclosure are not necessarily limited thereto.

The display device 10 may one of variously shapes. For example, the display device 10 has a shape such as a rectangle with a long width, a rectangle with a long length, a square, a rectangle with rounded corners (vertices), other polygons, or a circle. A shape of a display area DPA of the display device 10 is similar to an overall shape of the display device 10. FIG. 1 shows that the display device 10 and the display area DPA have a rectangular shape with a long width.

The display device 10 includes a display area DPA and a non-display area NDA. The display area DPA is where an image is displayed, and the non-display area NDA is where no image is displayed. The display area DPA may be referred to as an active area, and the non-display area NDA may be referred to as a non-active area. The display area DPA generally occupies the center of the display device 10.

The display area DPA includes a plurality of pixels PX. The plurality of pixels PX are arranged as a matrix. A shape of each pixel PX may be rectangular or square shaped in a plan view, but embodiments are not necessarily limited thereto, and may also be a rhombic shape in which each side is inclined with respect to one direction. Each pixel PX may be alternately arranged in a stripe type or a PenTile™ type. In addition, each of the pixels PX includes one or more light emitting elements ED that emit light in a specific wavelength band to display a specific color.

The non-display area NDA is disposed around the display area DPA. The non-display area NDA entirely or partially surrounds the display area DPA. The display area DPA has a rectangular shape, and the non-display area NDA is adjacent to four sides of the display area DPA. The non-display area NDA constitutes a bezel of the display device 10. Lines or circuit driving units in the display device 10 are disposed in the non-display areas NDA, and external devices may be mounted thereon.

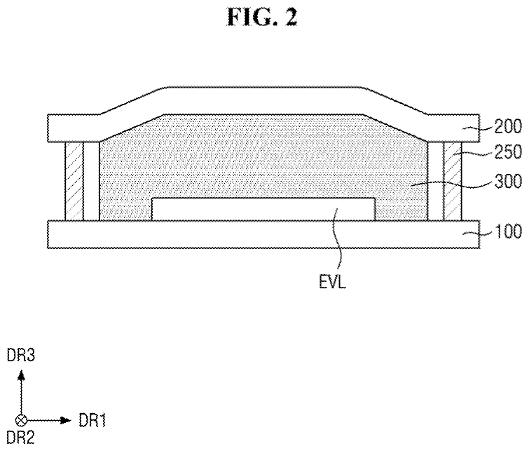

FIG. 2 is a schematic cross-sectional view of a display device according to an embodiment.

Referring to FIG. 2, the display device 10 according to an embodiment includes a substrate 100 and an opposing substrate 200 that faces the substrate 100, and also includes a sealing member 250 that couples the substrate 100 and the opposing substrate 200 and a filler 300 disposed between the substrate 100 and the opposing substrate 200. In addition, the display device 10 includes a display element layer EVL disposed on the substrate 100.

The substrate 100 serves as a base of the display device 10. The substrate 100 is made of a rigid material. In some embodiments, the substrate 100 includes glass, but embodiments are not necessarily limited thereto. For example, in some embodiments, the substrate 100 includes quartz.

The display element layer EVL is disposed on the substrate 100 in the third direction DR3. The display element layer EVL displays an image, and defines the display area DPA of the display device 10. For example, an area in which the display element layer EVL is disposed on the substrate 100 is the display area DPA, and an area in which the display element layer EVL is not disposed on the substrate 100 is the non-display area NDA. The display element layer EVL overlaps the display area DPA in the third direction DR3 and does not overlap the non-display area NDA in the third direction DR3.

The display element layer EVL includes elements and circuits that display an image, such as a pixel circuit such as a switching element, a conductive pattern and a self-light emitting element in the display area DPA to be described below. The self-light emitting element is at least one of an organic light emitting diode, a quantum dot light emitting diode, an inorganic material-based micro light emitting diode, such as a micro LED, or an inorganic material-based nano light emitting diode, such as a nano LED. Hereinafter, for convenience of description, a case where the self-light emitting element is an organic light emitting diode will be described by way of example.

The opposing substrate 200 is positioned on the substrate 100 and faces the substrate 100. In an embodiment, the opposing substrate 200 is a color conversion substrate that converts a color of incident light. The opposing substrate 200 is made of at least one of transparent glass or plastic, etc., and may be rigid or flexible.

The sealing member 250 is disposed between the substrate 100 and the opposing substrate 200 in the non-display area NDA. The sealing member 250 is disposed along edges of the substrate 100 and of the opposing substrate 200 in the non-display area NDA and surrounds the display area DPA in a plan view. The substrate 100 and the opposing substrate 200 are coupled to each other through the sealing member 250. The sealing member 250 may be made of an inorganic or an organic material. For example, the sealing member 250 is made of an inorganic material such as frit or an organic material such as an epoxy resin, but embodiments are not necessarily limited thereto.

The filler 300 is disposed in a space between the substrate 100 and the opposing substrate 200 and is surrounded by the sealing member 250. The filler 300 fills the space between the substrate 100 and the opposing substrate 200. In an embodiment, the filler 300 is made of a material that transmits light, such as a transparent material. The filler 300 is made of an organic material. The filler 300 will be described below.

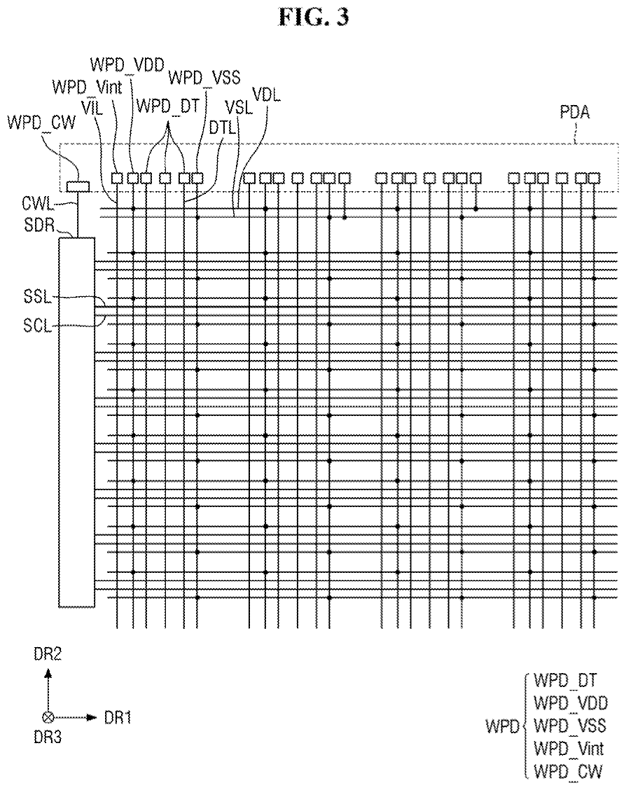

FIG. 3 illustrates lines in a display device according to an embodiment.

Referring to FIG. 3, in an embodiment, the display device 10 includes a plurality of lines. The plurality of lines includes a scan line SCL, a sensing line SSL, a data line DTL, an initialization voltage line VIL, a first voltage line VDL, and a second voltage line VSL. In addition, other lines may be further disposed in the display device 10.

The scan line SCL and the sensing line SSL extend in the first direction DR1. The scan line SCL and the sensing line SSL are connected to a scan driving unit SDR. The scan driving unit SDR includes a driving circuit. The scan driving unit SDR is disposed on one side of the display area DPA in the first direction DR1, but is not necessarily limited thereto. The scan driving unit SDR is connected to a signal line pattern CWL, and at least one end of the signal line pattern CWL is connected to an external device through a pad WPD_CW on the non-display area NDA.

In the present specification, the meaning of ‘connection’ means that one member is connected to another member through a mutual physical contact, as well as that one member is connected to another member through the other member. In addition, one portion and another portion as one integrated member are interconnected due to the integrated member. Furthermore, the connection between one member and another member may include an electrical connection through the other member in addition to a direct physically connection therebetween.

The data line DTL and the initialization voltage line VIL extend in a second direction DR2 that intersects the first direction DR1. The first voltage line VDL and the second voltage line VSL extend in the first and second directions DR1 and DR2. The first voltage line VDL and the second voltage line VSL are formed as conductive layers in which portions that extend in the first direction DR1 and portions that extend in the second direction are disposed on different layers, and have a mesh structure on the entire surface of the display area DPA. However, embodiments of the present disclosure are not necessarily limited thereto. Each of the pixels PX of the display device is connected to one or more data lines DTL, initialization voltage lines VIL, first voltage lines VDL, and second voltage lines VSL.

The data line DTL, the initialization voltage line VIL, the first voltage line VDL, and the second voltage line VSL are electrically connected to at least one line pad WPD. Each line pad WPD is disposed in the non-display area NDA. In an embodiment, a line pad WPD_DT, of the data line DTL, hereinafter referred to as a ‘data pad’, a line pad WPD_Vint of the initialization voltage line VIL, hereinafter referred to as an ‘initialization voltage pad’, a line pad WPD_VDD of the first voltage line VDL, hereinafter referred to as a ‘first power pad’, and a line pad WPD_VSS of the second voltage line VSL, hereinafter referred to as a ‘second power pad’, are disposed in a pad area PDA on one side of the display area DPA in the second direction DR2. An external device can be mounted on the line pad WPD. The external device is mounted on the line pad WPD through at least one of an anisotropic conductive film or an ultrasonic bonding, etc.

Each pixel PX or sub-pixel SPXn, where n is an integer of 1 to 3, of the display device 10 includes a pixel driving circuit. The above-described lines transmit a driving signal to each pixel driving circuit while passing through each pixel PX or passing around each pixel PX. The pixel driving circuit includes a transistor and a capacitor. The numbers of transistors and capacitors in each pixel driving circuit may vary. According to an embodiment, each sub-pixel SPXn of the display device 10 has a 3T1C structure in which the pixel driving circuit includes three transistors and one capacitor. Hereinafter, a pixel driving circuit will be described using the 3T1C structure as an example, but embodiments of the present disclosure are not necessarily limited thereto, and other embodiments include pixel PX structures such as a 2T1C structure, a 7T1C structure, or a 6T1C structure.

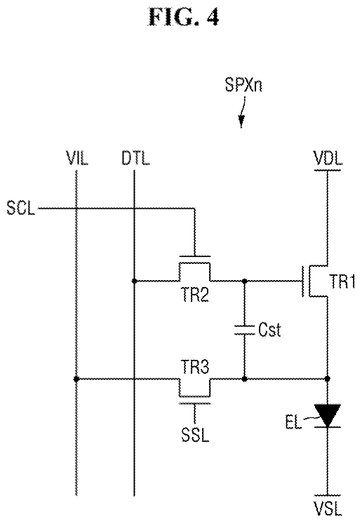

FIG. 4 is an equivalent circuit diagram of a sub-pixel according to an embodiment.

Referring to FIG. 4, each sub-pixel SPXn of the display device 10 according to an embodiment includes three transistors TR1, TR2, and TR3 and one storage capacitor Cst, in addition to a light emitting element EL.

The light emitting element EL emits light according to a current received through a first transistor TR1. The light emitting element EL includes a first electrode, a second electrode, and at least one light emitting layer disposed between the first electrode and the second electrode. The light emitting layer emits light in a specific wavelength band due to electrical signals received from the first electrode and the second electrode.

One end of the light emitting element EL is connected to a source electrode of the first transistor TR1, and the other end of the light emitting element EL is connected to the second voltage line VSL to which a low potential voltage, hereinafter referred to as a second power voltage, that is lower than a high potential voltage, hereinafter referred to as a first power voltage, of the first voltage line VDL is supplied. In addition, the other end of the light emitting element EL is connected to a source electrode of a third transistor TR3.

The first transistor TR1 adjusts a current flowing from the first voltage line VDL to which the first power voltage is supplied to the light emitting element EL according to a voltage difference between a gate electrode and the source electrode thereof. For example, the first transistor TR1 is a driving transistor that drives the light emitting element EL. The gate electrode of the first transistor TR1 is connected to a source electrode of the second transistor TR2, the source electrode of the first transistor TR1 is connected to the first electrode of the light emitting element EL, and a drain electrode of the first transistor TR1 is connected to the first voltage line VDL to which the first power voltage is supplied.

The second transistor TR2 is turned on by a scan signal of the scan line SCL to connect the data line DTL to the gate electrode of the first transistor TR1. A gate electrode of the second transistor TR2 is connected to the scan line SCL, the source electrode of the second transistor TR2 is connected to the gate electrode of the first transistor TR1, and a drain electrode of the second transistor TR2 is connected to the data line DTL.

The third transistor TR3 is turned on by a sensing signal of the sensing line SSL to connect the initialization voltage line VIL to one end of the light emitting element EL. A gate electrode of the third transistor TR3 is connected to the sensing line SSL, a drain electrode of the third transistor TR3 is connected to the initialization voltage line VIL, and a source electrode of the third transistor TR3 is connected to one end of the light emitting element EL or the source electrode of the first transistor TR1.

In an embodiment, the source electrode and the drain electrode of each of the transistors TR1, TR2, and TR3 are not necessarily limited to those described above, and vice versa. In addition, each of the transistors TR1, TR2, and TR3 is a thin film transistor. In addition, in an embodiment, each of the transistors TR1, TR2, and TR3 is formed as an N-type metal oxide semiconductor field effect transistor (MOSFET), however, embodiments of the present disclosure are not necessarily limited thereto. For example, in other embodiments, each of the transistors TR1, TR2, and TR3 is formed as a P-type MOSFET, or some of the transistors TR1, TR2, and TR3 are formed as an N-type MOSFET and other transistors TR1, TR2, and TR3 are formed as a P-type MOSFET.

The storage capacitor Cst is formed between the gate electrode and the source electrode of the first transistor TR1. The storage capacitor Cst stores a difference voltage between a gate voltage and a source voltage of the first transistor TR1.

Hereinafter, a structure of one pixel PX of the display device 10 according to an embodiment will be described in detail with reference to other drawings.

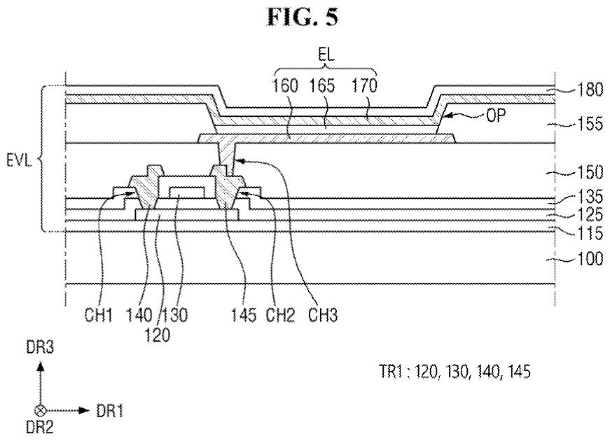

FIG. 5 is a schematic cross-sectional view illustrating one sub-pixel of the display device according to an embodiment. In FIG. 5, a structure of the display device 10 described above will be described in detail.

Referring to FIG. 5, the display device 10 according to an embodiment includes the display element layer EVL disposed on the substrate 100.

For example, a buffer layer 115 is disposed on the substrate 100. The buffer layer 115 is formed of an inorganic film that prevents permeation of air or moisture. The buffer layer 115 includes at least one of silicon compound or a metal oxide, etc. For example, the buffer layer 115 includes at least one of silicon oxide, silicon nitride, silicon oxynitride, aluminum oxide, tantalum oxide, hafnium oxide, zirconium oxide, or titanium oxide, etc. These oxides may be used alone or in combination with each other. The buffer layer 115 may be a single film or a multilayer film that includes stacked films of different materials.

The first transistor TR1 is disposed on the buffer layer 115. The first transistor TR1 includes a semiconductor layer 120, a gate electrode 130, a source electrode 140, and a drain electrode 145. The first transistor TR1 constitutes a pixel circuit of each of a plurality of pixels. For example, the first transistor TR1 is one of a driving transistor or a switching transistor of the pixel circuit. The drawing shows that one transistor is disposed in the sub-pixel SPX of the display device 10, and the transistor corresponds to the first transistor TR1 of FIG. 4 described above.

The semiconductor layer 120 is disposed on the buffer layer 115. The semiconductor layer 120 partially overlaps a gate electrode 130 of a first conductive layer to be described below

The semiconductor layer 120 includes at least one of polycrystalline silicon, single crystal silicon, or an oxide semiconductor, etc. In an embodiment, the semiconductor layer 120 also includes polycrystalline silicon. The oxide semiconductor contains indium (In). For example, the oxide semiconductor is at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), or indium gallium zinc tin oxide (IGZTO).

A gate insulating layer 125 is disposed on the semiconductor layer 120 and the buffer layer 115. The gate insulating layer 125 is a gate insulating film of the first transistor TR1. The gate insulating layer 125 includes at least one of a silicon compound or a metal oxide, etc. For example, the gate insulating layer 125 includes at least one of silicon oxide, silicon nitride, silicon oxynitride, aluminum oxide, tantalum oxide, hafnium oxide, zirconium oxide, or titanium oxide, etc. These oxides may be used alone or in combination with each other. The gate insulating layer 125 may be a single film or a multilayer film that includes stacked films of different materials.

The gate electrode 130 is disposed on the gate insulating layer 125. The gate electrode 130 overlaps a channel area of the semiconductor layer 120 in a third direction DR3, which is a thickness direction. The gate electrode 130 includes a metal. For example, the gate electrode 130 includes one or more metals of molybdenum (Mo), aluminum (Al), platinum (Pt), palladium (Pd), silver (Ag), magnesium (Mg), gold (Au), nickel (Ni), neodymium (Nd), iridium (Jr), chromium (Cr), calcium (Ca), titanium (Ti), tantalum (Ta), tungsten (W), or copper (Cu).

An interlayer insulating layer 135 is disposed on the gate electrode 130 and the gate insulating layer 125. The interlayer insulating layer 135 is an insulating film between the gate electrode 130 and the other layers disposed thereon. In addition, the interlayer insulating layer 135 covers the gate electrode 130 to protect the gate electrode 130.

The interlayer insulating layer 135 includes at least one of a silicon compound or a metal oxide, etc. For example, the interlayer insulating layer 135 includes at least one of silicon oxide, silicon nitride, silicon oxynitride, aluminum oxide, tantalum oxide, hafnium oxide, zirconium oxide, or titanium oxide, etc. These oxides may be used alone or in combination with each other. The interlayer insulating layer 135 may be a single film or a multilayer film that includes stacked films of different materials.

The source electrode 140 and the drain electrode 145 are disposed on the interlayer insulating layer 135. The source electrode 140 may be connected to the semiconductor layer 120 through a first contact hole CH1 that penetrates through the interlayer insulating layer 135 and the gate insulating layer 125. The drain electrode 145 is connected to the semiconductor layer 120 through a second contact hole CH2 that penetrates through the interlayer insulating layer 135 and the gate insulating layer 125.

The source electrode 140 and the drain electrode 145 include one or more of molybdenum (Mo), aluminum (Al), platinum (Pt), palladium (Pd), silver (Ag), magnesium (Mg), gold (Au), nickel (Ni), neodymium (Nd), iridium (Jr), chromium (Cr), calcium (Ca), titanium (Ti), tantalum (Ta), tungsten (W), or copper (Cu). The source electrode 140 and the drain electrode 145 may be a single film or a multilayer film.

A via layer 150 is disposed on the interlayer insulating layer 135, the source electrode 140 and the drain electrode 145. The via layer 150 provides a flat surface on which a first electrode 160 of the light emitting element EL can be formed.

The via layer 150 may include an inorganic insulating material or an organic insulating material such as at least one of a polyacrylates resin, an epoxy resin, a phenolic resin, a polyamides resin, a polyimides resin, an unsaturated polyesters resin, a polyphenyleneethers resin, a polyphenylenesulfides resin, or benzocyclobutene (BCB). The via layer 150 may be a single film or a multilayer film that includes stacked films of different materials.

The light emitting element EL is disposed on the via layer 150. The light emitting element EL includes a first electrode 160, a light emitting layer 165, and a second electrode 170.

The first electrode 160 is disposed on the via layer 150. The first electrode 160 is an anode electrode of the light emitting element EL. The first electrode 160 is connected to the drain electrode 145 of the first transistor TR1 through a third contact hole CH3 that penetrates through the via layer 150.

The first electrode 160 includes a transparent conductive material. For example, the first electrode 160 includes at least one of indium tin oxide (ITO), indium zinc oxide (IZO), or indium tin zinc oxide (ITZO). In some embodiments, the first electrode 160 includes a stack of one or more layers made of a transparent conductive material and one or more layers made of a highly reflective metal, or may be formed as one layer that includes the transparent conductive material and the highly reflective metal. For example, the first electrode 160 has a stacked structure of one of ITO/Ag/ITO, ITO/Ag/IZO, or ITO/Ag/ITZO/IZO.

A bank layer 155 is disposed on the first electrode 160. The bank layer 155 includes an opening OP that partially exposes the first electrode 160. The bank layer 155 covers edge portions of the first electrode 160. The bank layer 155 may be made of an organic insulating material or an inorganic insulating material. For example, the bank layer 155 includes at least one of a photoresist, a polyimide-based resin, an acrylic resin, a silicon compound, or a polyacrylic resin, etc.

The light emitting layer 165 is disposed on the first electrode 160 in the opening OP of the bank layer 155. The light emitting layer 165 further includes at least one of a hole injection layer, a hole transport layer, an electron transport layer, or an electron injection layer. The light emitting layer 165 emits one of red, blue, green light or white light for each sub-pixel SPX. When the light emitting layer 165 emits white light, red, blue, and green light can be displayed through an appropriate wavelength conversion member, respectively.

The second electrode 170 is disposed on the light emitting layer 165 and the bank layer 155. The second electrode 170 is disposed on the entire display area DPA of the substrate 100. The second electrode 170 is a common electrode disposed across the plurality of sub-pixels. The second electrode 170 is a cathode electrode of the light emitting element EL.

A capping layer 180 is disposed on the second electrode 170 of the light emitting element EL. The capping layer 180 protects the light emitting element EL. The capping layer 180 has a substantially constant thickness along a profile of the second electrode 170. The capping layer 180 may include an inorganic insulating material or an organic insulating material.

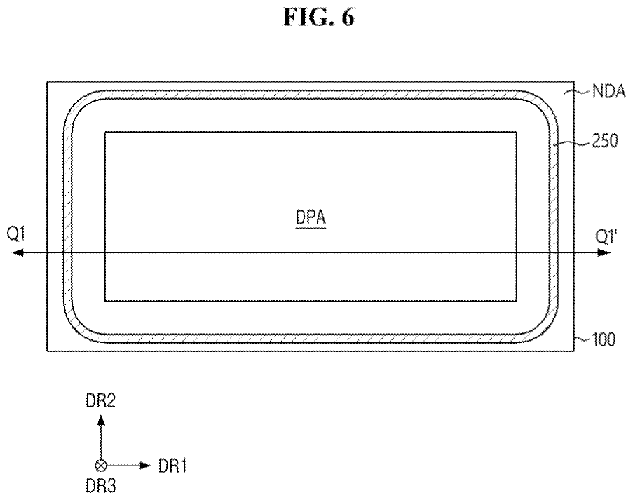

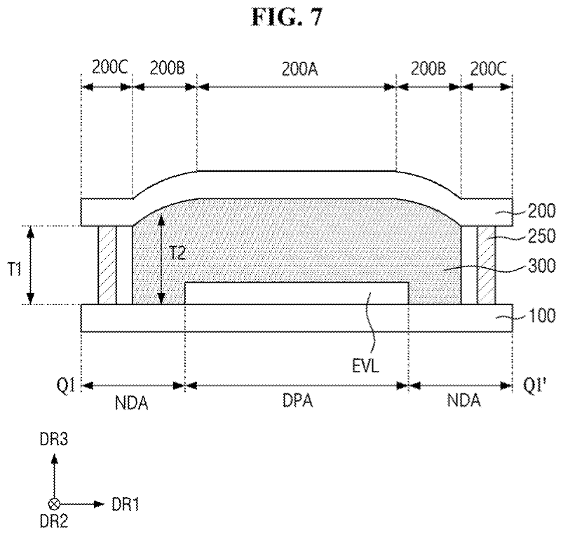

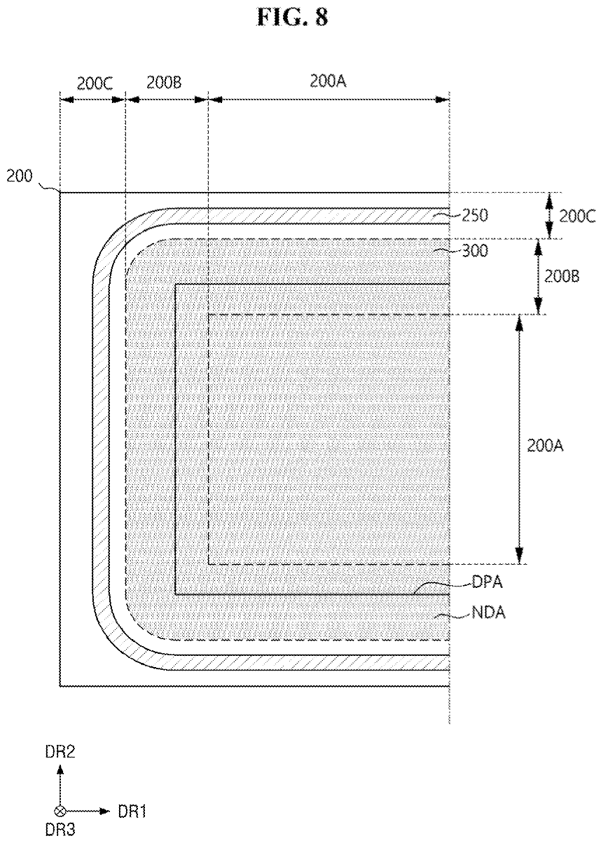

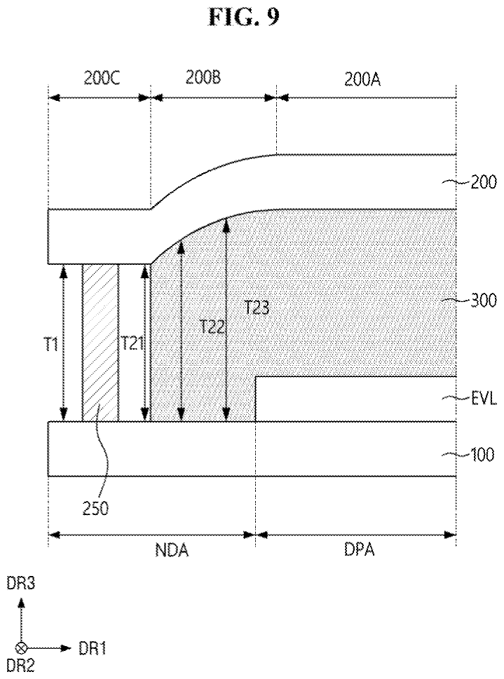

FIG. 6 is a plan view of a display device according to an embodiment. FIG. 7 is a cross-sectional view taken along line Q1-Q1′ of FIG. 6. FIG. 8 is a plan view of a portion of a display device according to an embodiment. FIG. 9 is a cross-sectional view of a portion of a display device according to an embodiment.

Referring to FIGS. 6 to 9, in an embodiment, the display device 10 includes a display area DPA and a non-display area NDA. The display area DPA is where a display element layer EVL is disposed, and overlaps the display element layer EVL in the third direction DR3. The non-display area NDA is an area other than the display area DPA, and does not overlap the display element layer EVL in the third direction DR3.

A sealing member 250 is disposed in the non-display area NDA of the display device 10 to couple the substrate 100 to the opposing substrate 200. A filler 300 is disposed between the substrate 100 and the opposing substrate 200. The filler 300 is disposed on the substrate 100 and covers the display element layer EVL. The filler 300 is in contact with an upper surface of the substrate 100 and is in contact with upper and side surfaces of the display element layer EVL. In addition, the filler 300 is in contact with one surface of the opposing substrate 200. For example, the filler 300 is in contact with a lower surface of the opposing substrate 200 that faces the substrate 100. The sealing member 250 and the filler 300 are spaced apart from each other. The sealing member 250 and the filler 300 are spaced apart from each other in the first and second directions DR1 and DR2 in a plan view.

The filler 300 reduces an empty space or an air layer between the substrate 100 and the opposing substrate 200 and prevents voids from occurring, thereby allowing a clear image to be displayed. The filler 300 made of a transparent material that can be easily applied. The filler 300 includes a polymer resin that contains silicon. For example, the silicon-containing polymer resin includes at least one of an acrylate resin that contains silicon, an epoxy resin that contains silicon, a vinyl-based resin that contains silicon, or a phenyl-based resin that contains silicon. In addition, the filler 300 includes an additive such as silylidyne (SiH) so that the polymer resin can be cured, and chemically connect silicones of the silicone-based polymer resin.

The filler 300 has a viscosity in the range of 1,000 to 100,000 cP for ease of application. For example, when the viscosity of the filler 300 is 1,000 cP or more, application of the filler 300 is easy, and when the viscosity of the filler 300 is 100,000 cP or less, the filler 300 can be prevented from discharging during application.

In an embodiment, the opposing substrate 200 has a curved shape. For example, the opposing substrate 200 includes a first area 200A, a second area 200B that surrounds the first area 200A, and a third area 200C that surrounds the second area 200B. The first area 200A, the second area 200B, and the third area 200C are divided according to a structure of the opposing substrate 200.

The first area 200A of the opposing substrate 200 corresponds to a central portion of the display device 10, and overlaps the substrate 100, the display element layer EVL, and the filler 300. As illustrated in FIG. 7, the display device 10 has a configuration in the first area 200A in which the display element layer EVL, the filler 300, and the opposing substrate 200 are sequentially disposed along the third direction DR3 from the substrate 100, and does not have an empty space. The first area 200A of the opposing substrate 200 is flat, without curves. For example, the first area 200A is parallel to the upper surface of the substrate 100.

The second area 200B of the opposing substrate 200 surrounds the first area 200A. A portion of the second area 200B overlaps the substrate 100, the filler 300, and the opposing substrate 200. Another portion of the second area 200B overlaps the substrate 100, the display element layer EVL, the filler 300, and the opposing substrate 200. The second area 200B of the opposing substrate 200 is curved. For example, the second area 200B has a convex surface that is curved upward toward the third direction DR3 from the substrate 100.

The second area 200B of the opposing substrate 200 surrounds the first area 200A. The third area 200C is where the substrate 100 and the opposing substrate 200 are coupled by the sealing member 250. In the third area 200C, the substrate 100, the sealing member 250, and the opposing substrate 200 overlap each other in that order. The third area 200C does not overlap the filler 300, and has an empty space disposed therein. The third area 200C of the opposing substrate 200 is flat. For example, the third area 200C is parallel to the upper surface of the substrate 100.

In an embodiment, heights of the first area 200A, the second area 200B, and the third area 200C of the opposing substrate 200 measured from the upper surface of the substrate 100 differ from each other.

For example, the height of the first area 200A of the opposing substrate 200 measured from the upper surface of the substrate 100 is higher than the heights of the second area 200B and the third area 200C measured from the upper surface of the substrate 100. The first area 200A of the opposing substrate 200 has a highest density when the filler 300 is applied, and is where the opposing substrate 200 protrudes to a highest height due to a thickness of the filler 300.

For example, the height of the second area 200B of the opposing substrate 200 measured from the upper surface of the substrate 100 is lower than the height of the first area 200A measured from the upper surface of the substrate 100, and is higher than the height of the third area 200C measured from the upper surface of the substrate 100. The second area 200B of the opposing substrate 200 is where the filler 300 spreads to an outer portion when the substrate 100 and the opposing substrate 200 are bonded after the application of the filler 300, and the height of the second area 200B gradually decreases as the filler 300 spreads to the outer portion. For example, the height of the second area 200B gradually decreases from the display area DPA toward the non-display area NDA.

The height of the third area 200C of the opposing substrate 200 measured from the upper surface of the substrate 100 is lower than the heights of the first area 200A and the second area 200B measured from the upper surface of the substrate 100. The third area 200C of the opposing substrate 200 is where the filler 300 does not spread and is not present. The height of the third area 200C is uniform within the third area 200C.

The sealing member 250 couples the substrate 100 and the opposing substrate 200. The sealing member 250 has a predetermined thickness to maintain a gap between the substrate 100 and the opposing substrate 200. In addition, the filler 300 has a predetermined thickness to maintain a gap between the substrate 100 and the opposing substrate 200. A thickness T2 of the filler 300 is determined in consideration of preventing display defects of the display element layer EVL caused by pressing the opposing substrate 200 and preventing the sealing member 250 from bursting.

In an embodiment, the thickness T2 of the filler 300 is in the range of 60% to 400% of a thickness T1 of the sealing member 250, and varies within the range of 60% to 400% of the thickness T1 of the sealing member 250. When the thickness T2 of the filler 300 is 60% or more of the thickness T1 of the sealing member 250, the occurrence of display defects generated by pressing the display element layer EVL when the substrate 100 and the opposing substrate 200 are bonded can be prevented. In addition, when the thickness T2 of the filler 300 is 400% or less of the thickness T1 of the sealing member 250, the sealing member 250 can be prevented from bursting when the substrate 100 and the opposing substrate 200 are bonded, which increases reliability.

As described above, the opposing substrate 200 has a shape that is convex in the third direction DR3. Accordingly, the thickness T2 of the filler 300 also varies. For example, the thickness T2 of the filler 300 is substantially uniform in an area that overlaps the first area 200A of the opposing substrate 200. For example, slight differences in the thickness T2 of the filler 300 may be present due to micro-curves on the upper surface of the display element layer EVL. Therefore, the thickness T2 of the filler 300 is ‘substantially’ uniform.

As illustrated in FIG. 9, in an embodiment, thicknesses T21, T22, and T23 of the filler 300 differ from each other in an area that overlaps the second area 200B of the opposing substrate 200. The thicknesses T21, T22, and T23 of the filler 300 in the second area 200B gradually increase from the sealing member 250 toward the display area DPA. For example, a first thickness T21 of the filler 300 adjacent to the sealing member 250 is the least, a second thickness T22 closer to the display area DPA is greater than the first thickness T21, and a third thickness T23 closer to the display area DPA is greater than the second thickness T22. For example, the first thickness T21 that corresponds to the side of the filler 300 is equal to the thickness T1 of the sealing member 250.

As described above, in the display device 10 according to an embodiment, the thickness of the filler 300 is in the range of 60 to 400% of the thickness of the sealing member 250, thereby preventing display defects and reliability deterioration.

Hereinafter, a display device 10 according to an embodiment will be described.

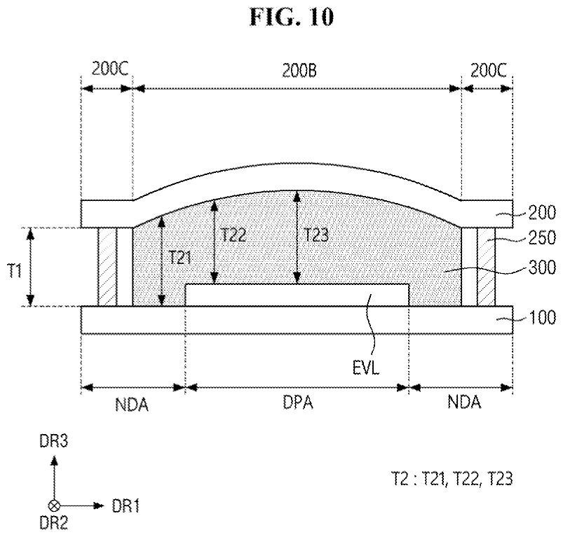

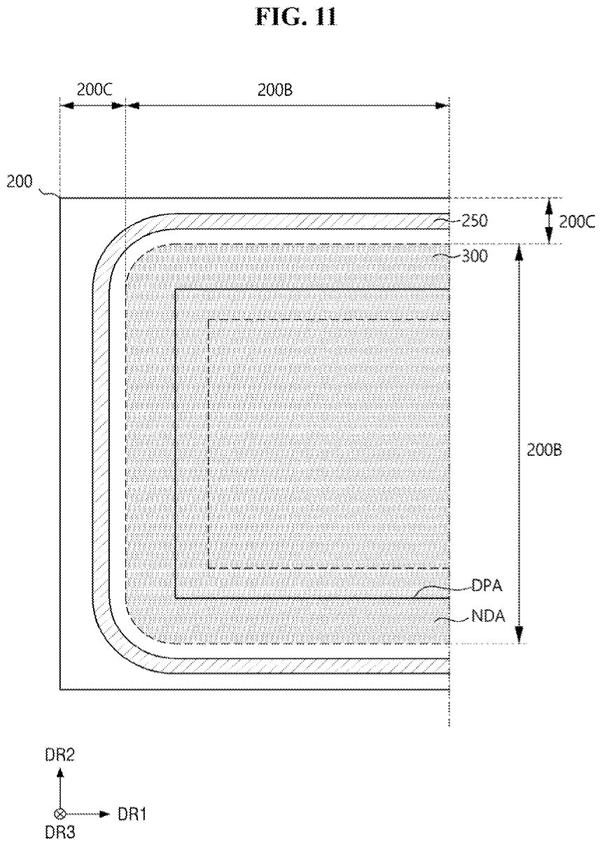

FIG. 10 is a cross-sectional view of a display device according to an embodiment. FIG. 11 is a plan view of a portion of a display device according to an embodiment.

Referring to FIGS. 10 and 11, an embodiment differs from an embodiment of FIGS. 6 to 9 described above in that there is no first area 200A of the opposing substrate 200. Hereinafter, repeated descriptions of an above-described embodiment will be omitted and differences thereof will be described.

The opposing substrate 200 has a curved shape. For example, the opposing substrate 200 includes a second area 200B and a third area 200C that surrounds the second area 200B.

The second area 200B of the opposing substrate 200 corresponds to most of the area that includes the central portion of the display device 10. The second area 200B of the opposing substrate 200 corresponds to an entirety of display area DPA and a portion of the non-display area NDA. The second area 200B overlaps the substrate 100, the display element layer EVL, and the filler 300. As illustrated in FIG. 10, in the second area 200B, the display device 10 has a configuration in which the display element layer EVL, the filler 300, and the opposing substrate 200 are sequentially disposed in the third direction DR3 from the substrate 100, and there is no empty space. The second area 200B of the opposing substrate 200 has a curved shape. For example, the second area 200B has a convex surface that is curved upward toward the third direction DR3 from the substrate 100. For example, the second area 200B has a convex surface that is curved toward the center of the display area DPA.

The third area 200C of the opposing substrate 200 surrounds the second area 200B and is the same as the third area 200C described above in an embodiment of FIGS. 6 to 9.

In an embodiment, heights of the second area 200B and the third area 200C of the opposing substrate 200 measured from the upper surface of the substrate 100 differ from each other.

For example, the height of the second area 200B of the opposing substrate 200 measured from the upper surface of the substrate 100 is higher than the height of the third area 200C measured from the upper surface of the substrate 100. The second area 200B of the opposing substrate 200 is where the filler 300 is substantially applied and spreads, and the height of the second area 200B of the opposing substrate 200 gradually decreases as the filler 300 spreads to an outer portion when the substrate 100 and the opposing substrate 200 are bonded. For example, the height of the second area 200B gradually decreases from the center of the display area DPA toward the non-display area NDA.

In an embodiment, the thickness T2 of the filler 300 is in a range of 60% to 400% of the thickness T1 of the sealing member 250. When the thickness T2 of the filler 300 is 60% or more of the thickness T1 of the sealing member 250, display defects generated by pressing the display element layer EVL when the substrate 100 and the opposing substrate 200 are bonded can be prevented from occurring. In addition, when the thickness T2 of the filler 300 is 400% or less of the thickness T1 of the sealing member 250, the sealing member 250 can be prevented from bursting when the substrate 100 and the opposing substrate 200 are bonded, which prevents a deterioration in reliability.

As described above, the opposing substrate 200 has a shape that is convex in the third direction DR3. Accordingly, the thickness T2 of the filler 300 also varies. As illustrated in FIG. 10, thicknesses T21, T22, and T23 of the filler 300 differ from each other in an area that overlaps the second area 200B of the opposing substrate 200. The thicknesses T21, T22, and T23 of the filler 300 in the second area 200B gradually increase from the sealing member 250 toward the center of the display area DPA. For example, the thicknesses T21, T22, and T23 of the filler 300 in the second area 200B gradually decrease from the center of the display area DPA toward the sealing member 250. For example, a first thickness T21 of the filler 300 adjacent to the sealing member 250 is the least, a second thickness T22 closer to the center of the display area DPA is greater than the first thickness T21, and a third thickness T23 at the center of the display area DPA is greater than the second thickness T22. For example, the first thickness T21 that corresponds to the side of the filler 300 is equal to the thickness T1 of the sealing member 250.

FIG. 10 appears to show that the first thickness T21 is the largest due to the display element layer EVL, but this is due to an exaggerated drawing of the display element layer EVL. Since the thickness of the display element layer EVL is substantially very small, the thickness T2 of the filler 300 is not limited to those shown in FIG. 10.

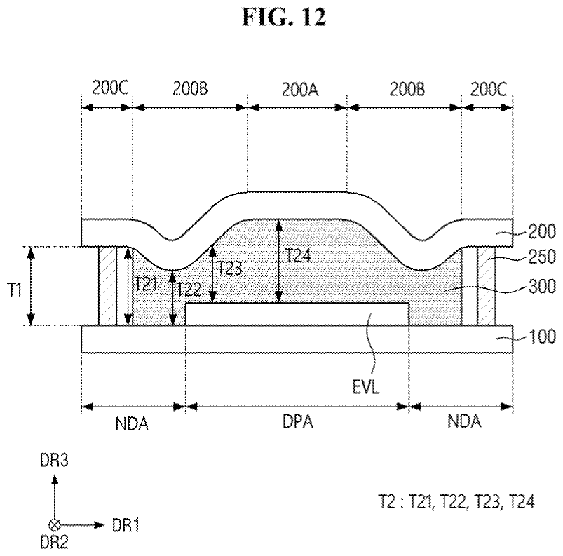

FIG. 12 is a cross-sectional view of a display device according to still another embodiment.

Referring to FIG. 12, an embodiment differs from an embodiment of FIGS. 6 to 9 described above in that the shape of the second area 200B of the opposing substrate 200 of the display device 10 is different. Hereinafter, repeated descriptions of an above-described embodiment will be omitted and differences from an above-described embodiment will be described.

The opposing substrate 200 has a curved shape. For example, the opposing substrate 200 includes a flat first area 200A, a curved second area 200B that surrounds the first area 200A, and a third area 200C that surrounds the second area 200B.

The second area 200B of the opposing substrate 200 surrounds the first area 200A. The second area 200B of the opposing substrate 200 is a curved area. For example, the second area 200B has as a concave surface that curves downward toward the substrate 100 in a direction opposite to the third direction DR3 and then a convex surface that curves upward toward the third direction DR3 toward a center of the opposing substrate 200. An area of the second area 200B that is curved downward toward the substrate 100 is adjacent to the non-display area NDA, and an area of the second area 200B that is curved upward away from the substrate 100 is disposed adjacent to the center of the display area DPA. The area of concave portion of the second area 200B is where the filler 300 is relatively thin and that is pressed by stress. The area of the convex portion of the second area 200B is where the filler 300 is relatively thick and protrudes convexly as it approaches the center of the display area DPA.

In an embodiment, the second area 200B of the opposing substrate 200 has different heights as measured from the upper surface of the substrate 100.

For example, the height of the second area 200B of the opposing substrate 200 measured from the upper surface of the substrate 100 is lower than the height of the first area 200A measured from the upper surface of the substrate 100. The second area 200B of the opposing substrate 200 is where the filler 300 is substantially applied and spreads, and the height of the second area 200B of the opposing substrate 200 gradually decreases and then increases as the filler 300 spreads to an outer portion when the substrate 100 and the opposing substrate 200 are bonded. For example, the height of the second area 200B gradually decreases from the center of the display area DPA toward the non-display area NDA and then gradually increases at an edge of the non-display area NDA.

In an embodiment, the thickness T2 of the filler 300 is in a range of 60% to 400% of the thickness T1 of the sealing member 250. When the thickness T2 of the filler 300 is 60% or more of the thickness T1 of the sealing member 250, display defects generated due to pressing of the display element layer EVL when the substrate 100 and the opposing substrate 200 are bonded can be prevented from occurring. In addition, when the thickness T2 of the filler 300 is 400% or less of the thickness T1 of the sealing member 250, the sealing member 250 can be prevented from bursting when the substrate 100 and the opposing substrate 200 are bonded, which prevents a deterioration in reliability.

As described above, the opposing substrate 200 has a shape that becomes concave in a direction opposite to the third direction DR3 and then convex in the third direction DR3 from the non-display area NDA toward the center of the display area DPA. Accordingly, the thickness T2 of the filler 300 varies. As illustrated in FIG. 12, thicknesses T21, T22, T23, and T24 of the filler 300 differ from each other in an area that overlaps the first area 200A and the second area 200B of the opposing substrate 200. In the first area 200A, the thickness T24 of the filler 300 is the thickest. The thicknesses T21, T22, and T23 of the filler 300 in the second area 200B gradually decrease from the sealing member 250 toward the center of the display area DPA and then increase again. For example, the thicknesses T21, T22, and T23 of the filler 300 in the second area 200B gradually decrease from the center of the display area DPA toward the sealing member 250 and then increase again. For example, compared to the first thickness T21 of the filler 300 adjacent to the sealing member 250, the second thickness T22 closer to the center of the display area DPA is thinner. In addition, the third thickness T23 closer to the center of the display area DPA than the second thickness T22 is greater than the second thickness T22. In this case, the first thickness T21 that corresponds to the side of the filler 300 is equal to the thickness T1 of the sealing member 250.

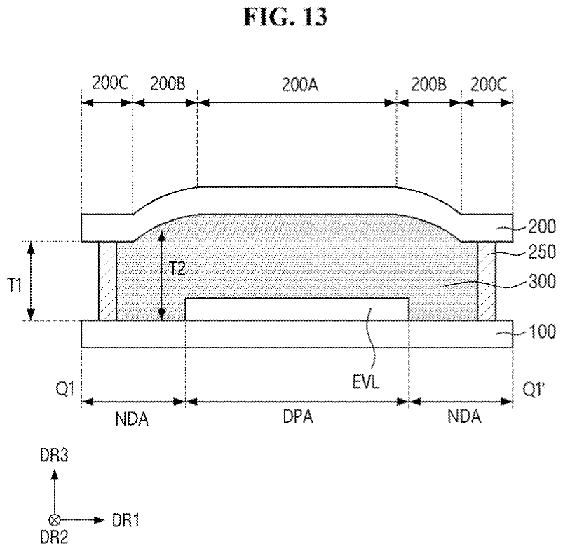

FIG. 13 is a cross-sectional view of a display device according to an embodiment.

Referring to FIG. 13, an embodiment differs from an embodiment of FIGS. 6 to 9 in that the filler 300 is in contact with the sealing member 250.

The filler 300 completely fills the space between the substrate 100 and the opposing substrate 200 bonded by the sealing member 250. For example, there is no empty space between the substrate 100 and the opposing substrate 200 where no filler 300 is present. The filler 300 is in direct contact with the sealing member 250 as well as in contact with the substrate 100 and the opposing substrate 200.

As the filler 300 completely fills the space between the substrate 100 and the opposing substrate 200, permeation of moisture and oxygen into the display element layer EVL is prevented and durability of the display device 10 is further increased.

Hereinafter, a method of manufacturing the display device 10 according to an embodiment will be described.

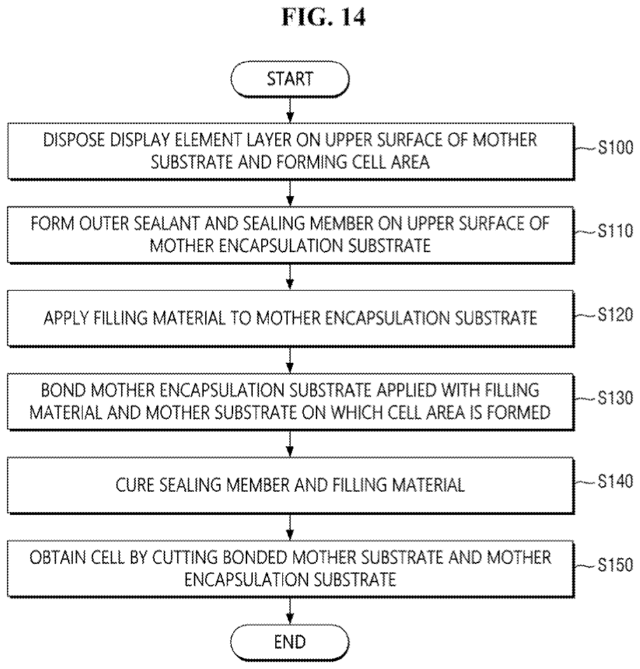

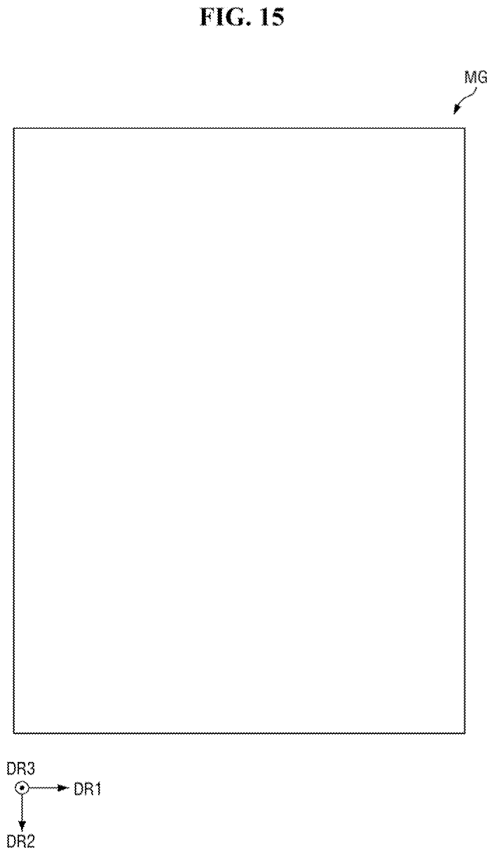

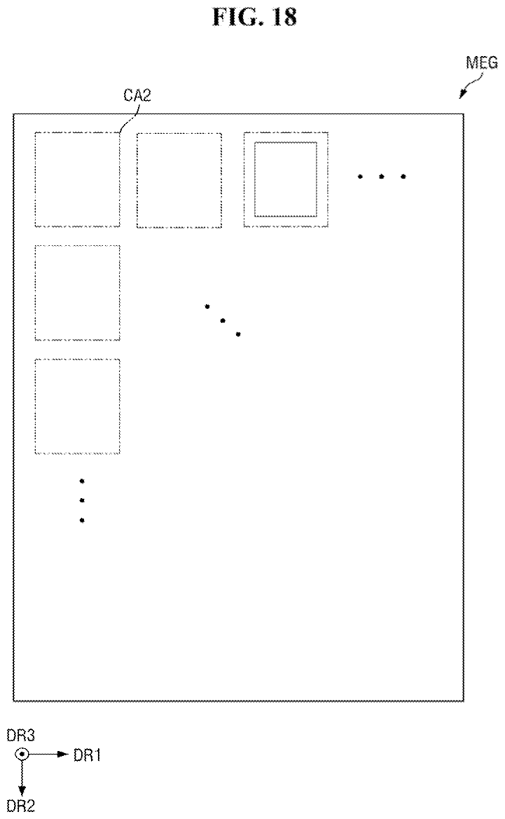

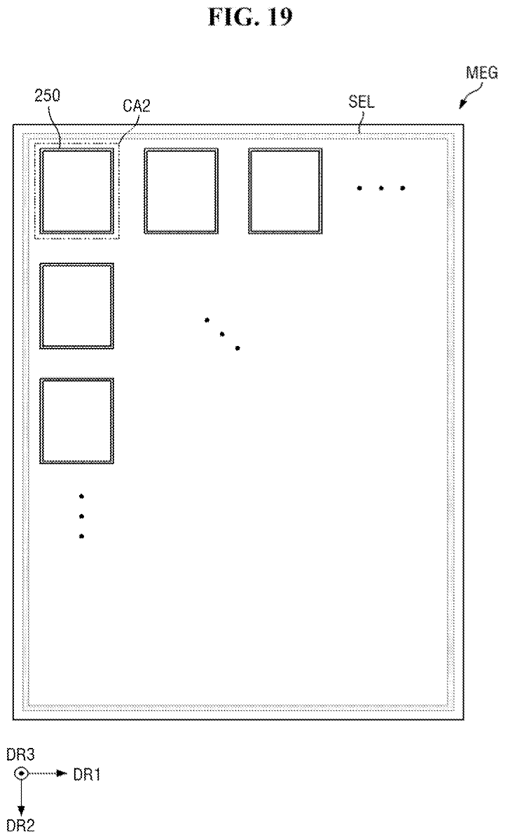

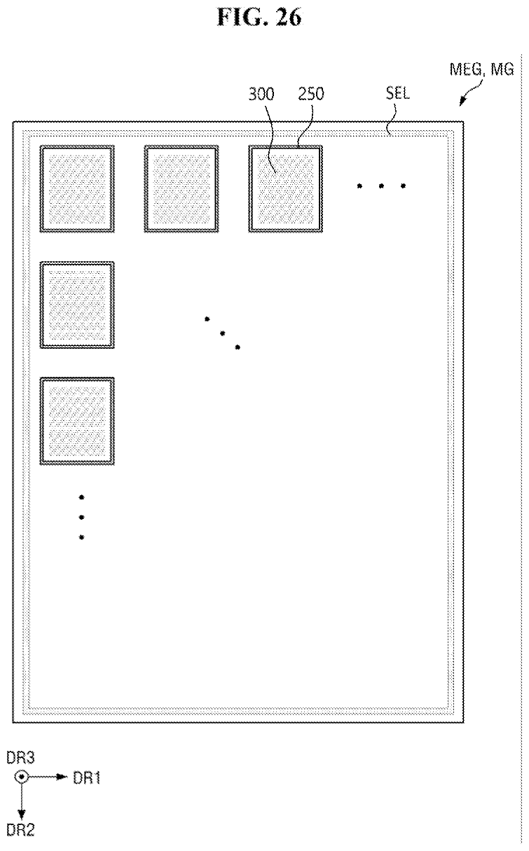

FIGS. 14 to 28 illustrate a method of manufacturing a display device according to an embodiment. FIG. 14 is a flowchart of a method for manufacturing a display device according to an embodiment. FIGS. 15 to 28 illustrate a method for manufacturing a display device according to an embodiment.

Referring to FIG. 14, a method of manufacturing a display device 10 according to an embodiment includes disposing a display element layer EVL on an upper surface of a mother substrate MG and forming a cell area (S100), forming an outer sealant SEL and a sealing member 250 on an upper surface of a mother encapsulation substrate MEG (S110), applying a filling material 300′ to the mother encapsulation substrate MEG (S120), bonding the mother encapsulation substrate MEG applied with the filling material 300′ and the mother substrate MG on which the cell area is formed (S130), curing the sealing member 250 and the filling material 300′ (S140), and obtaining a cell by cutting the bonded mother substrate MG and mother encapsulation substrate MEG (S150). Hereinafter, the process steps will be sequentially described.

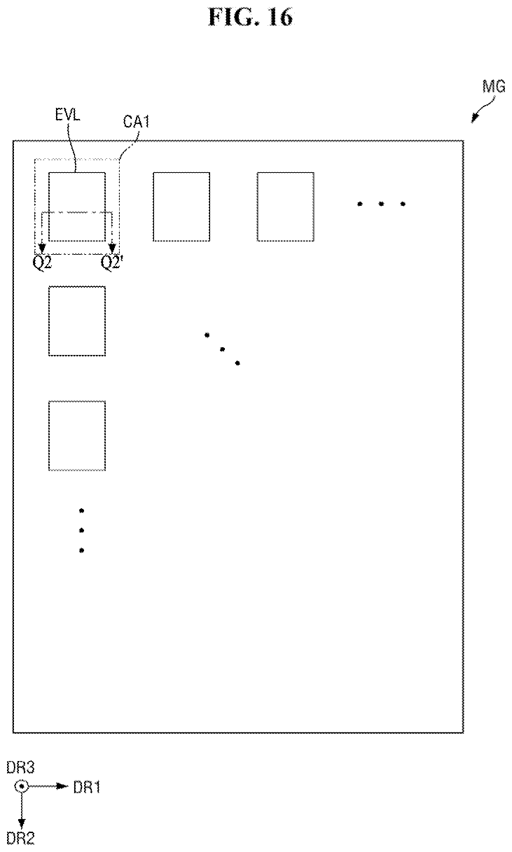

Referring to FIGS. 15 and 16, in an embodiment, a mother substrate MG is prepared, and a display element layer EVL is disposed on an upper surface of the mother substrate MG to form a cell area. For example, a process of disposing the display element layer EVL is a deposition process.

The mother substrate MG includes the same material as the substrate 100, and has a plurality of cell areas formed thereon to obtain a plurality of display devices 10 at once. Each cell area corresponds to one display device 10. The cell area defined on the mother substrate MG is referred to as a first cell area CA1 for convenience. An area of the mother substrate MG that corresponds to the first cell area CA1 becomes the substrate 100 through a cutting process, which will be described below. In some embodiments, the first cell areas CA1 are arranged in a grid pattern on the mother substrate MG.

A plurality of display elements are disposed in a grid pattern on the mother substrate MG. The display element layer EVL is disposed in a plurality of first cell areas CA1. Since a process of disposing the display element layer EVL is well known to those skilled in the art, a detailed description thereof will be omitted.

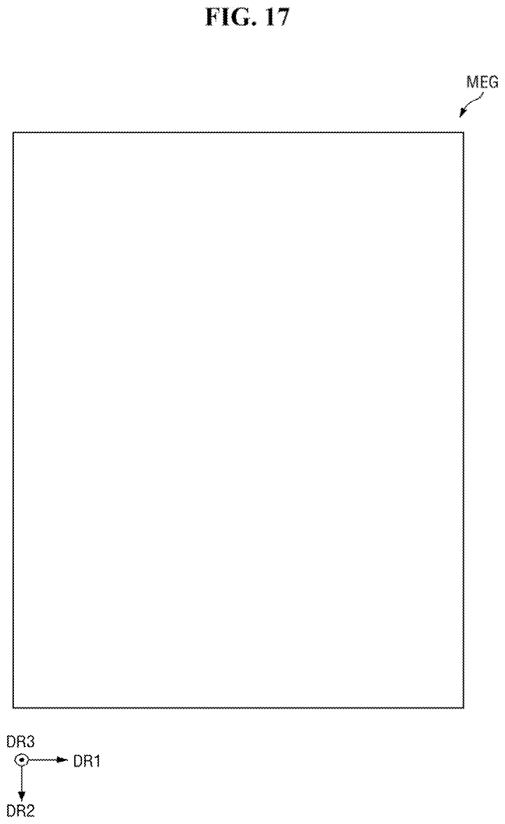

Referring to FIGS. 17 to 19, in an embodiment, an outer sealant SEL and a sealing member 250 are formed on one surface of a mother encapsulation substrate MEG.

The mother encapsulation substrate MEG includes the same material as the opposing substrate 200, and has a plurality of cell areas formed thereon to obtain a plurality of display devices 10 at once. As described above, each cell area corresponds to one display device 10. The cell area defined on the mother encapsulation substrate MEG is referred to as a second cell area CA2 for convenience. An area that corresponds to the second cell area CA2 of the mother encapsulation substrate MEG becomes the opposing substrate 200 through a cutting process, which will be described below. The second cell area CA2 of the mother encapsulation substrate MEG overlaps the first cell area CA1 of the mother substrate MG in a process of bonding the mother encapsulation substrate MEG and the mother substrate MG. In some embodiments, the second cell areas CA2 are arranged in a grid pattern on the mother encapsulation substrate MEG.

The outer sealant SEL couples edges of the mother encapsulation substrate MEG and the mother substrate MG. Since the outer sealant SEL is disposed along the edge of the mother encapsulation substrate MEG, the second cell area CA2 is disposed inside the outer sealant SEL. For example, the outer sealant SEL encloses the second cell area CA2.

The sealing member 250 couples an edge of the first cell area CA1 of the mother substrate MG to an edge of the second cell area CA2 of the mother encapsulation substrate MEG. The outer sealant SEL and the sealing member 250 are applied by a dispensing method.

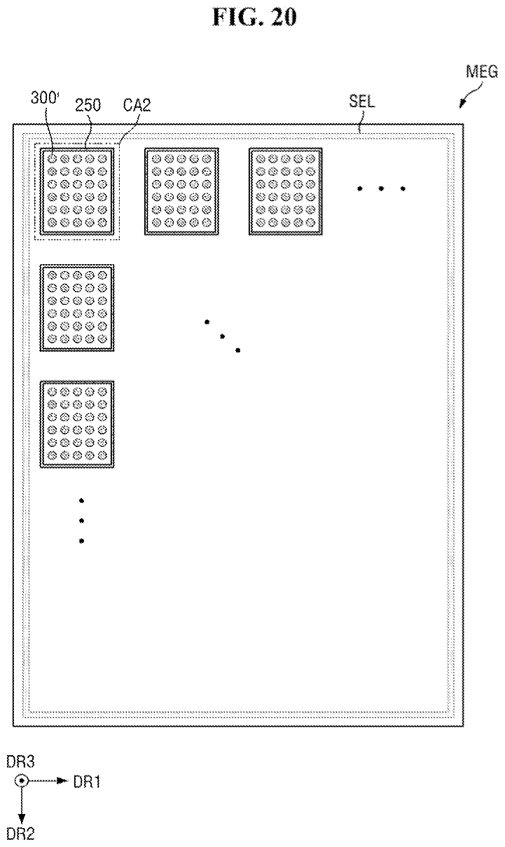

Referring to FIG. 20, in an embodiment, a filling material 300′ is applied on the mother encapsulation substrate MEG on which the sealing member 250 is formed. For example, the filling material 300′ is applied as a plurality of dots through a jet dispenser.

When the plurality of dots of the filling material 300′ is applied in a grid pattern, the filling material 300′ evenly spreads in a subsequent process of bonding the mother substrate MG and the mother encapsulation substrate MEG. The drawing shows that five dots of the filling material 300′ are applied in the first direction DR1 per surface modification area HPA, but the number of applied dots of the filling material 300′ is not necessarily limited thereto. In addition, the filling material 300′ is applied to be spaced apart from the sealing member 250.

The filling material 300′ includes the same material and composition as the filler 300. For example, the filling material 300′ includes a material that has little reactivity with the display element layer EVL, such as at least one of an acrylate-based resin containing silicon, an epoxy-based resin containing silicon, a vinyl-based resin containing silicon, or a phenyl-based resin containing silicon. In addition, the filling material 300′ has a refractive index of 1.4 or more and 1.5 or less. The filling material 300′ forms the filler 300 through a curing process to be described below. For example, the filler 300 is obtained by curing the filling material 300′.

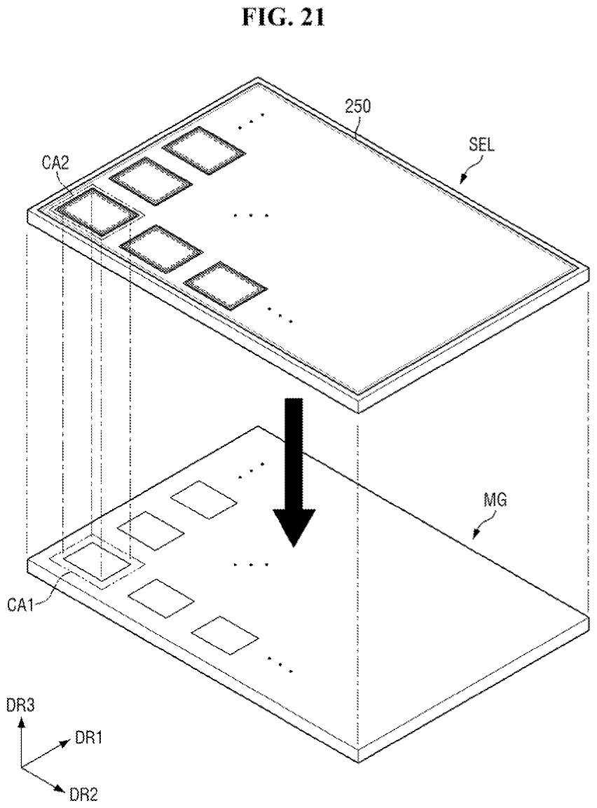

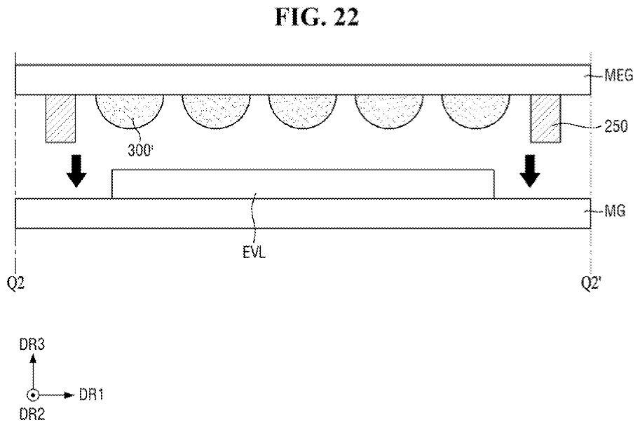

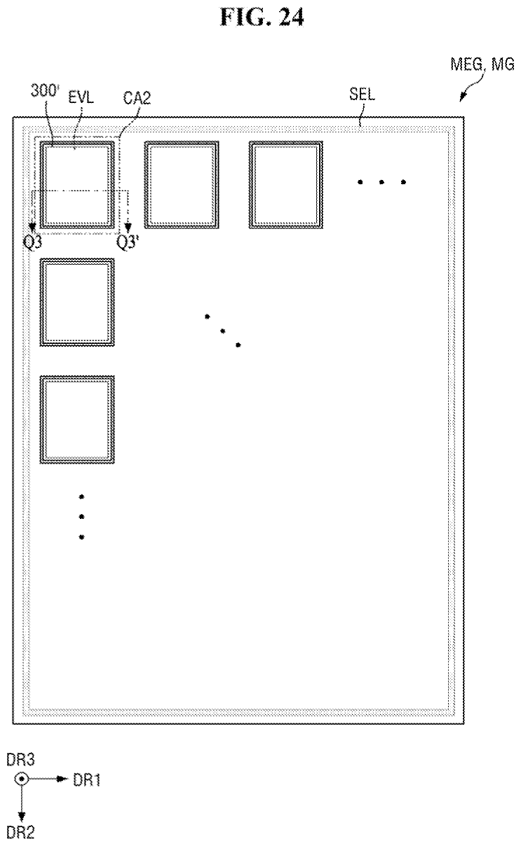

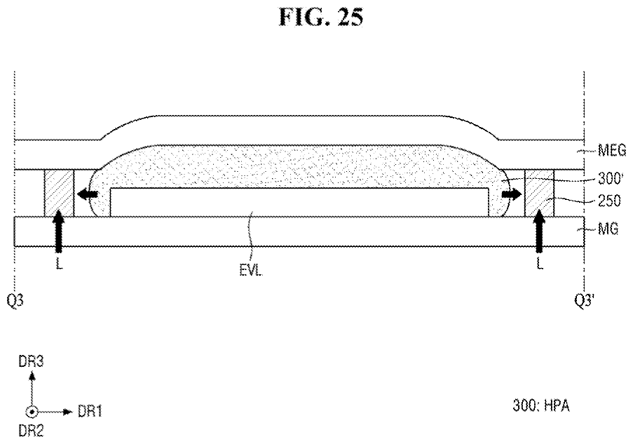

Referring to FIGS. 21 to 26, in an embodiment, the mother encapsulation substrate MEG applied with the filling material 300′ and the mother substrate MG are bonded. For example, a process of bonding the mother substrate MG and the mother encapsulation substrate MEG is a thermo-compression process that applies a laser to the sealing member 250. FIG. 22 schematically illustrates a cross section cut along the line Q2-Q2′ in FIG. 16, and FIG. 25 schematically illustrates a cross section cut along the line Q3-Q3′ in FIG. 24.

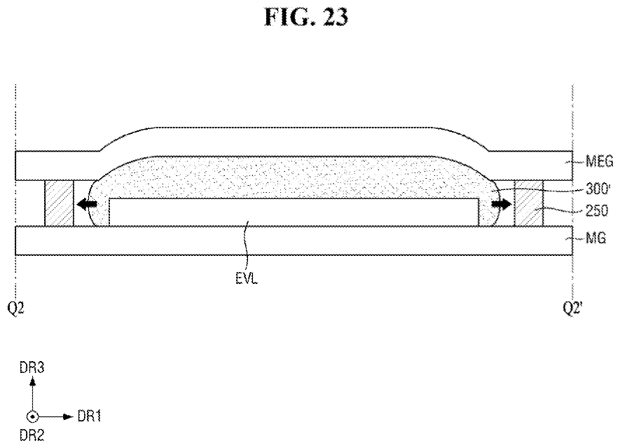

The process of bonding the mother encapsulation substrate MEG and the mother substrate MG is performed when the display element layer EVL on the mother substrate MG and the mother encapsulation substrate MEG face each other. When the mother encapsulation substrate MEG and the mother substrate MG are bonded, the filling material 300′ applied onto the mother encapsulation substrate MEG spreads due to a thickness of the display element layer EVL formed on the mother substrate MG, as illustrated in FIG. 23.

For example, the filling material 300′ spreads toward the sealing member 250 in a space surrounded by the mother encapsulation substrate MEG, the mother substrate MG, and the sealing member 250, as illustrated in FIGS. 23 and 24. The filling material 300′ remains spaced apart from the sealing member 250 for a predetermined time without coming into contact with the sealing member 250.

In addition, when the mother encapsulation substrate MEG is bonded to the mother substrate MG, the mother encapsulation substrate MEG acquires a shape that is convex in the third direction DR3 by the applied filling material 300′. The mother encapsulation substrate MEG becomes convex in the third direction DR3 in an area that faces the display element layer EVL and has a relatively large amount of the filling material 300′, and the convex region flattens as a whole. The mother encapsulation substrate MEG has a gently curved surface in an area adjacent to the sealing member 250 around the display element layer EVL. In addition, the mother encapsulation substrate MEG is flat without changing a shape thereof in an area that overlaps the sealing member 250.

Referring to FIG. 25, in an embodiment, the sealing member 250 is irradiated with a laser beam L that partially melts the sealing member 250 so that the mother substrate MG and the mother encapsulation substrate MEG can be bonded. Since the filling material 300′ does not reach the sealing member 250 and does not come into contact with the sealing member 250 when the sealing member 250 is irradiated with the laser beam L, the filling material 300′ is not affected by thermal energy by the laser beam L or thermal energy by the sealing member 250 itself.

If the filling material 300′ reaches and comes into contact with the sealing member 250 when the sealing member 250 is irradiated with the laser beam L, the filling material 300′ may be affected by thermal energy by the laser beam L or by the sealing member 250 itself, so that gas may be discharged from the filling material 300′, which can damage the display element layer EVL. Accordingly, such a situation can be resolved by controlling spreading characteristics of the filling material 300′ applied onto the mother encapsulation substrate MEG.

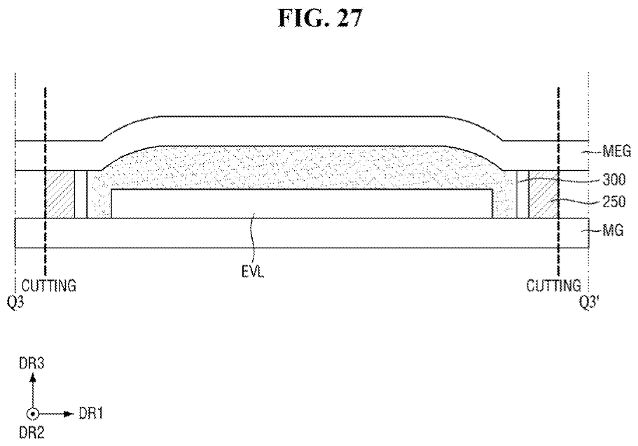

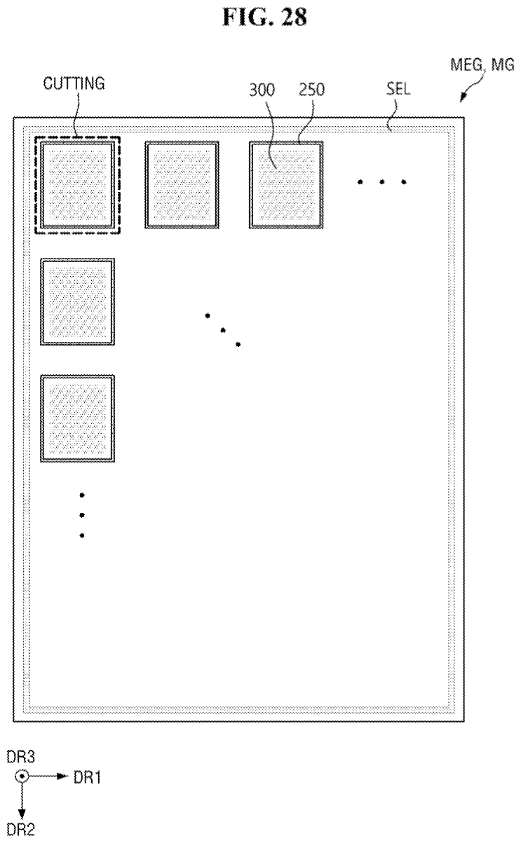

Referring to FIGS. 27 and 28, in an embodiment, a filler 300 is formed by curing the filling material 300′ after the filling material 300′ has spread into the space surrounded by the mother encapsulation substrate MEG, the mother substrate MG, and the sealing member 250. For example, a process of curing the filling material 300′ includes at least one of thermal curing, UV curing, or thermal curing and UV curing at the same time. For example, the filling material 300′ can spread into the space surrounded by the mother encapsulation substrate MEG, the mother substrate MG, and the sealing member 250 but remain spaced apart from the sealing member 250. However, the filling material 300′ is not necessarily limited thereto and can come into contact with the sealing member 250. The filling material 300′ completely covers the display element layer EVL.

The filler 300 has a different thickness for each area according to the convex shape of the mother encapsulation substrate MEG. As described in FIGS. 7 to 9, the thickness of the filler 300 can vary within the range of 60% to 400% of the thickness of the sealing member 250. For example, the thickness of the filler 300 gradually increases from the non-display area NDA toward the display area DPA. The thickness of the filler 300 is uniform in the first area 200A of the opposing substrate 200, and gradually increases from the second area 200B toward the first area 200A.

The display device 10 of FIG. 7 is obtained by cutting the cell area. In the display device according to the embodiment, mechanical stability and image visibility are increased.

In concluding the detailed description, those skilled in the art will appreciate that many variations and modifications can be made to embodiments without substantially departing from the principles of embodiments of the present disclosure. Therefore, embodiments of the disclosure are used in a generic and descriptive sense only and not for purposes of

What is claimed is:

1. A display device, comprising:
a substrate that includes a display area and a non-display area;
a display element layer disposed on the display area of the substrate;
an opposing substrate that faces the substrate and the display element layer;
a sealing member disposed on the non-display area and that couples the substrate and the opposing substrate; and
a filler disposed between the substrate and the opposing substrate,
wherein a thickness of the filler ranges from 60% to 400% of a thickness of the sealing member.

2. The display device of claim 1, wherein the thickness of the filler increases from the non-display area toward the display area.

3. The display device of claim 1, wherein the thickness of the filler increases from the non-display area toward a center of the display area.

4. The display device of claim 1, wherein the thickness of the filler decreases and then increases from the sealing member toward a center of the display area.

5. The display device of claim 1, wherein the substrate and the opposing substrate each include glass.

6. The display device of claim 1, wherein the filler is in direct contact with the substrate, the display element layer, and the opposing substrate.

7. The display device of claim 1, wherein the filler includes at least one of an acrylate resin that contains silicon, an epoxy resin that contains silicon, a viny-based resin that contains silicon, or a phenyl-based resin that contains silicon.

8. The display device of claim 7, wherein the filler further comprises silylidyne.

9. The display device of claim 1, wherein the filler is spaced apart from the sealing member and covers the display element layer.

10. The display device of claim 1, wherein the filler is in contact with the sealing member and fills a space between the substrate and the opposing substrate.

11. The display device of claim 10, wherein the filler has a viscosity of 1,000 to 100,000 cP.

12. A display device, comprising:
a substrate;
a display element layer disposed on the substrate;
an opposing substrate that faces the substrate and includes a first area that overlaps the display element layer, a second area that surrounds the first area, and a third area that surrounds the second area;
a sealing member that couples the substrate and the opposing substrate; and
a filler that covers the display element layer and is in contact with the substrate and the opposing substrate,
wherein the filler has different thicknesses in the first area, the second area, and the third area.

13. The display device of claim 12, wherein heights of the first area, the second area, and the third area of the opposing substrate measured from an upper surface of the substrate differ from each other.

14. The display device of claim 13, wherein the height of the first area is higher than the height of each of the second area and the third area.

15. The display device of claim 13, wherein the height of the second area increases from the third area toward the first area.

16. The display device of claim 13, wherein the height of the second area decreases and then increases from the third area toward the first area.

17. The display device of claim 12, wherein the first area and the third area are flat.

18. The display device of claim 12, wherein the third area overlaps the sealing member.

19. The display device of claim 12, wherein the thickness of the filler ranges from 60% to 400% of a thickness of the sealing member.

20. The display device of claim 12, wherein the filler has a viscosity of 1,000 to 100,000 cP.

21. A method of manufacturing a display device, comprising:
disposing a display element layer on an upper surface of a mother substrate and forming a plurality of first cell areas;
forming an outer sealant and a sealing member on an upper surface of a mother encapsulation substrate, wherein the mother encapsulation substrate includes a plurality of second cell areas that overlap the plurality of first cell areas;
applying a filling material to the mother encapsulation substrate;
bonding the mother encapsulation substrate to the mother substrate, wherein the mother encapsulation substrate acquires a shape that is convex in a third direction perpendicular to the upper surface of the mother substrate by the applied filling material;
curing the sealing member and the filling material wherein a filler is formed, and
obtaining a display device by cutting the bonded mother substrate and mother encapsulation substrate.

22. The method of claim 21, wherein a plurality of display elements are disposed in a grid pattern on the mother substrate, and the display element layer is disposed in each of the plurality of first cell areas.

23. The method of claim 21, wherein the second cell areas are arranged in a grid pattern on the mother encapsulation substrate, and the outer sealant couples edges of the mother encapsulation substrate and the mother substrate and encloses the second cell areas.

24. The method of claim 21, wherein the filling material is applied as a plurality of dots in a grid pattern through a jet dispenser, and are spaced apart from the sealing member.

25. The method of claim 21, wherein the filling material includes a material that has little reactivity with the display element layer and has a refractive index of 1.4 or more and 1.5 or less.

26. The method of claim 21, wherein bonding the mother substrate and the mother encapsulation substrate includes a thermo-compression process that applies a laser to the sealing member, wherein the filling material spreads toward the sealing member in a space surrounded by the mother encapsulation substrate, the mother substrate, and the sealing member, and the mother encapsulation substrate becomes convex in the third direction in an area that faces the display element layer.

27. The method of claim 26, wherein the sealing member is irradiated with a laser beam that partially melts the sealing member so that the mother substrate and the mother encapsulation substrate are bonded to each other.

28. The method of claim 21, wherein curing the sealing member and the filling material includes at least one of thermal curing, UV curing, or thermal curing and UV curing at the same time.
